(19) United States
(12) Patent Application Publication
(10) Pub. No.: US 2026/0053002 A1
(43) Pub. Date: Feb. 19, 2026

(54) Semiconductor structure including alignment mark and measuring method thereof

(71) Applicant: UNITED MICROELECTRONICS CORP., Hsin-Chu City (TW)

(72) Inventors: Yi-Jing Wang, Tainan City (TW); Chien-Hao Chen, Tainan City (TW); Chang-Mao Wang, Tainan City (TW); Chun-Chi Yu, Taipei City (TW)

(73) Assignee: UNITED MICROELECTRONICS CORP., Hsin-Chu City (TW)

(21) Appl. No.: 18/829,226

(22) Filed: Sep. 9, 2024

(30) Foreign Application Priority Data
Aug. 13, 2024 (TW) 113130233

(51) Int. Cl. H01L 23/544; H01L 21/66

(52) U.S. Cl. CPC H01L 23/544; H01L 22/12; H01L 2223/54426

(57) ABSTRACT

The invention provides a semiconductor structure including alignment marks, which comprises a substrate defining a peripheral region, a first gate structure located in the peripheral region on the substrate, wherein the first gate structure has a left boundary and a right boundary, a dielectric layer covers the first gate structure in the peripheral region, a first left slot contact groove located in the dielectric layer on the left side of the first gate structure, a first right slot contact groove located in the dielectric layer on the right side of the first gate structure, and a first gate opening exposing a left boundary and a right boundary of the first gate structure, a boundary of the first left slot contact groove and a boundary of the first right slot contact groove.

### BACKGROUND OF THE INVENTION

### 1. Field of the Invention

The invention relates to the field of semiconductor manufacturing, in particular to a semiconductor structure including an alignment mark and a measuring method thereof.

### 2. Description of the Prior Art

In the semiconductor manufacturing process, overlay and alignment mark are two important technical concepts. These technologies ensure that the wafer can be accurately aligned in each layer of the multi-layer structure, thus ensuring the function and performance of the circuit. With the continuous progress of process technology, the importance of these technologies has gradually increased.

With the continuous progress of process technology, the requirements for overlay accuracy and alignment marks are getting higher and higher. In advanced process nodes, the overlay error needs to be controlled within a few nanometers, which puts high demands on process equipment and technology. In order to meet these challenges, new alignment and correction technologies are constantly introduced into the process technology. However, the application of this technology has also brought some new challenges, such as stricter requirements for photoresist materials and mask design.

### SUMMARY OF THE INVENTION

The invention provides semiconductor structure with alignment marks, it includes a substrate defining a peripheral region, a first gate structure located in the peripheral region on the substrate, wherein the first gate structure has a left boundary and a right boundary, a dielectric layer covers the first gate structure in the peripheral region, a first left slot contact groove located in the dielectric layer on a left side of the first gate structure, a first right slot contact groove located in the dielectric layer on a right side of the first gate structure, and a first gate opening exposing the left boundary of the first gate structure, the right boundary of the first gate structure, a boundary of the first left slot contact groove and a boundary of the first right slot contact groove.

The invention further provides a method for measuring a semiconductor structure including an alignment mark. The method includes: providing a substrate, defining a peripheral region thereon, forming an alignment mark in the peripheral region, and the alignment mark including: a first gate structure located in the peripheral region on the substrate, wherein the first gate structure has a left boundary and a right boundary, a dielectric layer covers the gate structure in the peripheral region, a first left slot contact groove located in the dielectric layer on a left side of the first gate structure, a first right slot contact groove located in the dielectric layer on a right side of the first gate structure, and a first gate opening exposing the left boundary of the first gate structure, the right boundary of the first gate structure, a boundary of the first left slot contact groove and a boundary of the first right slot contact groove.

In the prior art, even if the first gate structure is formed in the peripheral region, the first gate structure is usually not regarded as a part of the alignment mark. The reason is that the first gate structure located in the peripheral region will be covered by the dielectric layer later, so from the top view, it is not easy to observe the position of the first gate structure, and the relative position of the first gate structure and other devices cannot be observed. The invention is characterized in that when the second gate opening is formed in the core region, the first gate opening is also formed in the peripheral region, wherein the first gate opening exposes the boundary of the first gate structure, the right boundary of the first left slot contact groove and the left boundary of the first right slot contact groove, so that the boundaries of the above elements become visible, and further comprising the left boundary of the first left slot contact groove and the right boundary of the first right slot contact groove which are originally visible from the top view direction. The boundaries of the above components can measure the distance from each other, and then calculate whether the relative position between the components is offset. Therefore, from the manufacturer's point of view, the position offset between the components can be found at the early stage of the process, and then the process parameters can be corrected to reduce the displacement and improve the quality of the components.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIGS. 1 and 2 are schematic cross-sectional views of a semiconductor structure according to an embodiment of the present invention.

FIG. 3 is a top view of the first gate structure, the first slot contact groove and the first gate opening in the peripheral region, and the second gate structure, the second slot contact groove and the second gate opening in the core region in FIG. 2.

FIG. 4 is a schematic cross-sectional view of filling a metal layer into each groove according to the structure shown in FIG. 2.

FIG. 5 and FIG. 6 are schematic top views of the first gate structure, the first slot contact groove and the first gate opening in the peripheral region according to two other embodiments of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about”or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

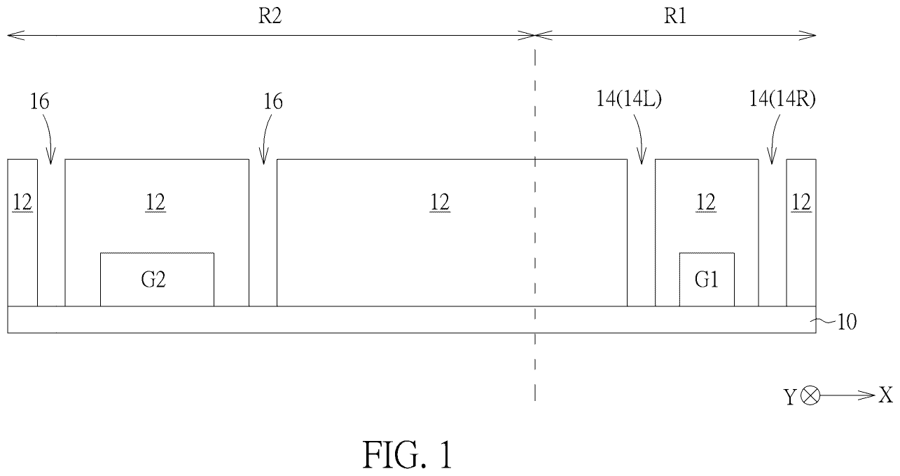

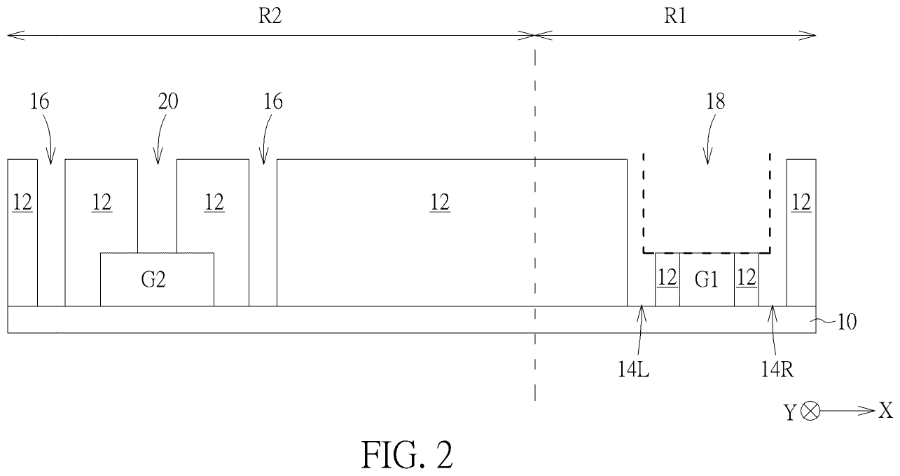

Please refer to FIG. 1 and FIG. 2, which are schematic cross-sectional views of a semiconductor structure according to an embodiment of the present invention. As shown in FIG. 1, a peripheral region R1 and a core region R2 are defined on a substrate 10, wherein the substrate 10 is, for example, a silicon substrate of a wafer, or other substrates such as silicon-on-insulator (SOI), and the present invention is not limited to this. The core region R2 is, for example, the device region on the wafer, that is, the main formation region of various electronic components (such as transistors, resistors, capacitors, conductive lines, etc.) in the subsequent process, while the peripheral region R1 is, for example, a scribe line or other dummy region on the wafer, which is usually located next to the device region, and the components formed in the peripheral region R1 will not be regarded as the main electronic components in the subsequent process. In the current manufacturing process, some dummy elements, test elements or alignment marks can be arranged in the peripheral region R1 to effectively use the space in the peripheral region R1. In the present invention, an alignment mark will be formed in the peripheral region R1, and the characteristics of this alignment mark will be described in the following paragraphs.

Next, a first gate structure G1 is formed in the peripheral region R1 on the substrate 10, and a second gate structure G2 is formed in the core region R2. The first gate structure G1 and the second gate structure G2 can be formed in the same process, for example, they can be formed in the same photolithography process using the same mask, and the first gate structure G1 and the second gate structure G2 can contain the same material, such as polysilicon, but the present invention is not limited to this. The second gate structure G2 formed in the core region R2 serves as the gate structure of the main electronic components (such as transistors) in the subsequent process, while the first gate structure G1 formed in the peripheral region R1 serves as a part of the alignment mark. In more detail, in the subsequent step, the first gate structure G1 formed in the peripheral region R1 may overlay with other elements formed in the peripheral region R1, and then calculate whether mis-alignment occurs between components.

In addition, structures such as source region, drain region and shallow trench isolation (STI) may be formed in the substrate 10. These devices are preferably formed in the core region R2 as a part of the subsequent transistor structure. The source region, drain region, shallow trench isolation (STI) and other structures are not drawn here for the sake of simplicity, but those skilled in the art should understand that these elements may exist in the semiconductor structure of the present invention.

Referring to FIG. 1, after the first gate structure G1 and the second gate structure G2 are completed, a dielectric layer 12 is formed to cover the substrate 10, the first gate structure G1 and the second gate structure G2. The dielectric layer 12 is made of insulating materials such as silicon oxide, silicon nitride and silicon oxynitride, but the present invention is not limited to this. Then, a plurality of contact holes, such as slot contact grooves, are formed in the dielectric layer 12. As shown in FIG. 1, first slot contact grooves 14 are formed in the peripheral region R1, in which two first slot contact grooves 14 are located on both sides of the first gate structure G1. Here, for the sake of clarity, the first slot contact groove 14 located on the left side of the first gate structure G1 is defined as the first left side slot contact groove 14L, and the first slot contact groove 14 located on the right side of the first gate structure G1 is defined as the first right side slot contact groove 14R. Similarly, second slot contact grooves 16 are formed in the core region R2, wherein two second slot contact grooves 16 are located at two sides of the second gate structure G2. The slot contact groove described here is preferably a strip-shaped groove from the top view, and a metal layer will be filled in the subsequent step to make the slot contact grooves become slot contacts. The slot contact in the core region R2 is used as a contact structure for electrically connecting transistors, which can electrically connect the source/drain below and other circuit layers or electronic components above. As for the first slot contact groove 14 formed in the peripheral region R1, it is preferable that the first slot contact groove 14 and the second slot contact groove 16 are formed at the same time, for example, they can be formed in the same photolithography process using the same mask. However, the first slot contact groove 14 in the peripheral region R1 is not used as a contact structure to electrically connect with other elements. In this embodiment, the first slot contact groove 14 can be used as a part of the alignment mark to overlap with the first gate structure G1, so as to calculate whether an alignment error occurs between elements. The knowledge about slot contact belongs to the prior art in this field, and will not be repeated here.

Referring to FIG. 2, a first gate opening 18 is formed in the peripheral region R1 and a second gate opening 20 is formed in the core region R2. In the subsequent process, the second gate opening 20 is filled with a metal layer together with the second slot contact grooves 16 to form contact structures, and are electrically connected to the second gate structure G2. While making the second gate opening 20, the first gate opening 18 can be formed in the peripheral region R1 at the same time. It should be noted that the width of the first gate opening 18 is wider than that of the first gate structure G1, and the boundary of the first gate opening 18 (indicated by dashed lines in FIG. 2) overlaps with the range of part of the first slot contact groove 14.

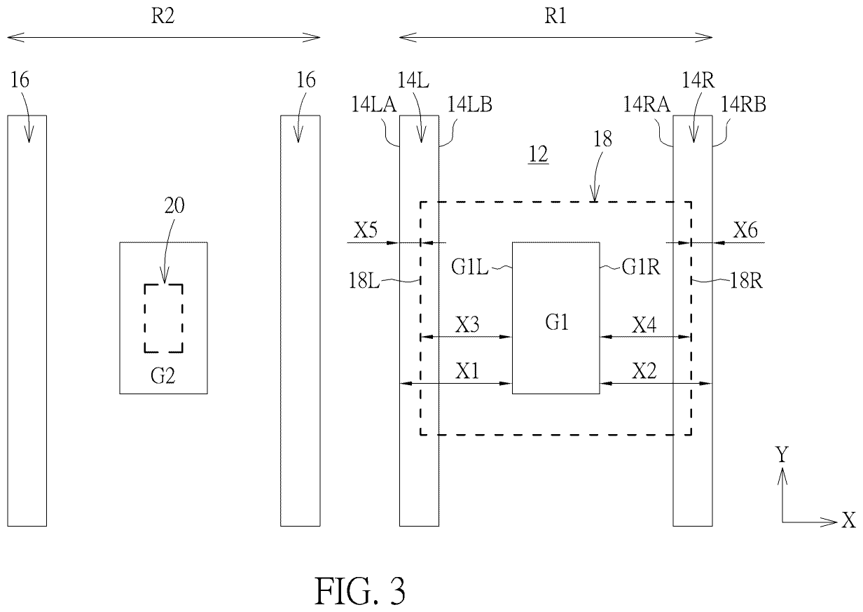

Please refer to FIG. 3, which shows the top view of the first gate structure, the first slot contact groove and the first gate opening in the peripheral region R1, and the second gate structure, the second slot contact groove and the second gate opening in the core region R2 in FIG. 2. In FIG. 3, each element includes a left boundary and a right boundary. The so-called left boundary is the boundary near the −X direction and extending along the Y direction, while the right boundary is the boundary near the +X direction and along the Y direction. Here, the left boundary of the first gate structure G1 is defined as G1L, the right boundary of the first gate structure G1 is defined as G1R, the left boundary of the first gate opening 18 is defined as 18L, the right boundary of the first gate opening 18 is defined as 18R, the left boundary of the first left slot contact groove 14L is defined as 14LA, the right boundary of the first left slot contact groove 14L is defined as 14LB, and the left boundary of the first right slot contact groove 14R is defined as 14RA. As mentioned above, the left boundary 18L of the first gate opening 18 overlaps with the range of the first left slot contact groove 14L, and the right boundary 18R of the first gate opening 18 overlaps with the range of the first right slot contact groove 14R. Therefore, when viewed from the top, the first gate opening 18 exposes the left boundary G1L and the right boundary G1R of the first gate structure G1, the right boundary 14LB of the first left slot contact groove 14L, and the first right slot contact groove 14R.

In the prior art, when the second gate structure G2, the second slot contact groove 16 and the second gate opening 20 are formed in the core region R2, it is not necessary to also form the first gate structure G1, the first slot contact groove 14 and the first gate opening 18 in the peripheral region R1. And even if the first gate structure G1 is formed in the peripheral region R1, the first gate structure G1 is generally not regarded as a part of the alignment mark. The reason is that the first gate structure G1 located in the peripheral region R1 will be covered by the dielectric layer 12, so it is not easy to observe the position of the first gate structure G1 from the top view, and it is also difficult to observe the relative position between the first gate structure G1 and the first slot contact groove 14 (because the first gate structure G1 was already covered by the dielectric layer 12 when the first slot contact groove 14 was formed). The feature of the present invention is that the second gate opening 20 can be formed in the core region R2 and the first gate opening 18 can be formed in the peripheral region R1 at the same time. The width of the first gate opening 18 here is wider than that of the first gate structure G1, and the boundary of the first gate structure G1 and part of the first slot contact groove 14 is exposed. Therefore, from the top view, the first gate opening 18 has a function similar to that of an observation window. In addition, the position of the first gate opening 18 also corresponds to the position of the second gate opening 20 in the core region R2. Therefore, by measuring the relative position between the boundary of the first gate opening 18 and the boundary of the first gate structure G1, or measuring the relative position between the boundary of the first gate opening 18 and the boundary of the first slot contact groove 14, it can also be confirmed whether the mis-alignment occurs among the first gate opening 18, the first gate structure G1 and the first slot contact groove 14.

More specifically, in an embodiment of the present invention, if the manufacturer needs to confirm whether there is an mis-alignment deviation between the first gate structure G1 and the first slot contact groove 14, the distance from the left boundary 14LA of the first left slot contact groove 14L to the left boundary G1L of the first gate structure G1 in the X direction can be measured and defined as a first distance X1. And measure that distance from the right boundary 14RB of the first right slot contact groove 14R to the right boundary G1R of the first gate structure G1, defining it as a second distance X2, and then subtract the first distance X1 from the second distance X2 and dividing by 2 to obtain a first alignment value. The first alignment value described here represents the relative positions of the first left slot contact groove 14L, the first right slot contact groove 14R and the first gate structure G1 in the X direction. If the first alignment value is 0, it means that the distance from the first left slot contact groove 14L to the first gate structure G1 in the X direction is equal to the distance from the first right slot contact groove 14R to the first gate structure G1, that is, the first gate structure G1 is located at the midline between the first left slot contact groove 14L and the first right slot contact groove 14R. On the other hand, if the first alignment value is not 0, the first gate structure G1 may shift to the left or right, so the manufacturer can adjust the process parameters by observing the first alignment value.

In another embodiment of the present invention, if the manufacturer needs to confirm whether there is a mis-alignment deviation between the first gate structure G1 and the first gate opening 18, the manufacturer can measure the distance from the left boundary 18L of the first gate opening 18 to the left boundary G1L of the first gate structure G1 in the X direction, and define it as a third distance X3, and measure the distance from the right boundary 18R of the first gate opening 18 to the right boundary G1R of the first gate structure G1, and define it as a fourth distance X4. And then subtract the third distance X3 from the fourth distance X4 and dividing by 2 to obtain a second alignment value. The second alignment value described here represents the relative position of the first gate opening 18 and the first gate structure G1 in the X direction. If the second alignment value is 0, it means that the midline position of the first gate opening 18 and the midline position of the first gate structure G1 overlap in the X direction, that is, they are aligned with each other in the X direction. On the other hand, if the second alignment value is not 0, the relative position between the first gate structure G1 and the first gate opening 18 may shift to the left or right, so the manufacturer can adjust the process parameters by observing the second alignment value.

In another embodiment of the present invention, if the manufacturer needs to confirm whether there is an mis-alignment deviation between the first slot contact groove 14 and the first gate opening 18, the distance from the left boundary 18L of the first gate opening 18 to the left boundary 14LA of the first left slot contact groove 14L in the X direction can be measured and defined as the fifth distance X5. And measuring the distance from the right edge 18R of the first gate opening 18 to the right edge 14RB of the first right slot contact groove 14R, and defining it as a sixth distance X6, and then subtracting the fifth distance X5 from the sixth distance X6 and dividing it by 2 to obtain a third alignment value. The third alignment value here represents the relative position of the first gate opening 18 and the first slot contact groove 14 in the X direction. If the third alignment value is 0, it means that the distance from the first left slot contact groove 14L to the first gate opening 18 in the X direction is equal to the distance from the first right slot contact groove 14R to the first gate opening 18, that is, the first gate opening 18 is located at the midline between the first left slot contact groove 14L and the first right slot contact groove 14R. Otherwise, if the third alignment value is not 0, the first gate opening 18 may shift to the left or right.

Therefore, as shown in the above three different embodiments, the present invention is characterized in that the second gate opening 20 is formed in the core region R2 and the first gate opening 18 is also formed in the peripheral region R1. The first gate opening 18 exposes the left boundary G1L of the first gate structure G1, the right boundary G1R of the first gate structure G1, the right boundary 14LB of the first left slot contact groove 14L and the left boundary 14RA of the first right slot contact groove 14R, which makes the boundaries of the above elements visible, together with the left boundary 14LA of the first left slot contact groove 14L and the right boundary 14R which are originally visible from the top view. The boundaries of the above components can measure the distance from each other, and then calculate whether the relative position between the components is offset. Therefore, from the manufacturer's point of view, the position offset between the components can be found at the early stage of the process, and then the process parameters can be corrected to reduce the displacement and improve the quality of the components.

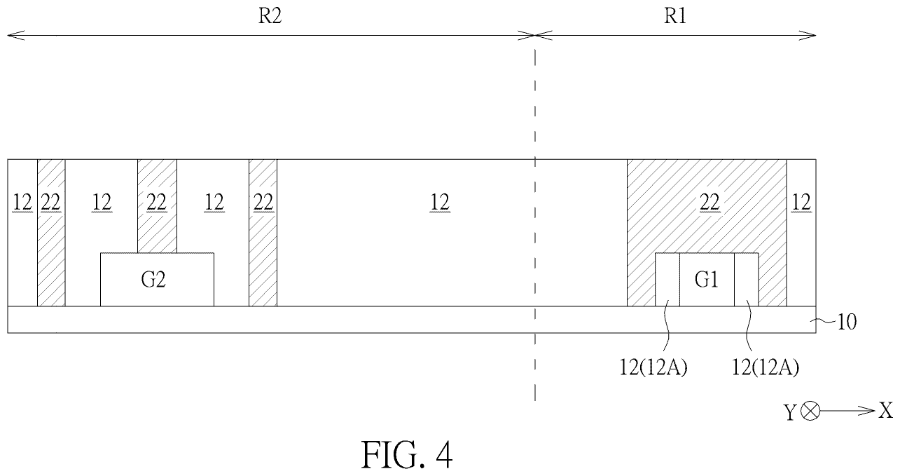

Subsequently, please refer to FIG. 4, which shows the schematic cross-sectional structure of filling a metal layer into each groove according to the structure shown in FIG. 2. As shown in FIG. 4, a metal layer 22 is filled into the second gate opening 20 and the second slot contact groove in the core region R2, and into the first gate opening 18 and the first slot contact groove 14 in the peripheral region R1. The material of the metal layer 22 described here is, for example, a metal with good conductivity such as tungsten, cobalt, copper, aluminum, gold, silver, etc., but the present invention is not limited to this. As mentioned above, the metal layer 22 is filled into the second gate opening 20 and the second slot contact groove in the core region R2 to form a gate contact structure and a slot contact structure, respectively, for connecting the gate, source/drain and other elements of the transistor (such as a circuit layer or an electronic element to be formed later). The first gate opening 18 and the first slot contact groove 14 in the peripheral region R1 are also filled with the metal layer 22. In addition, from the cross-sectional view, in the peripheral region R1, a part of the dielectric layer 12 (defined as the dielectric layer 12A in FIG. 4) is located between the first gate structure G1 and the metal layer 22, and the top surface of this part of the dielectric layer 12A is flush with the top surface of the first gate structure G1.

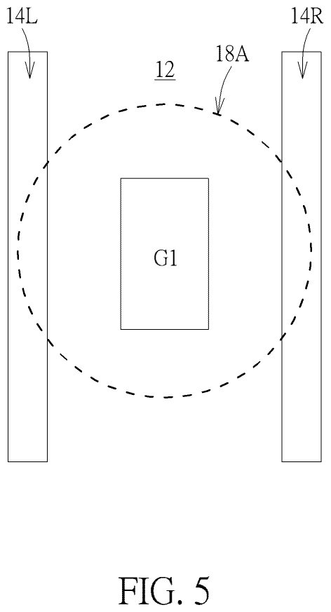

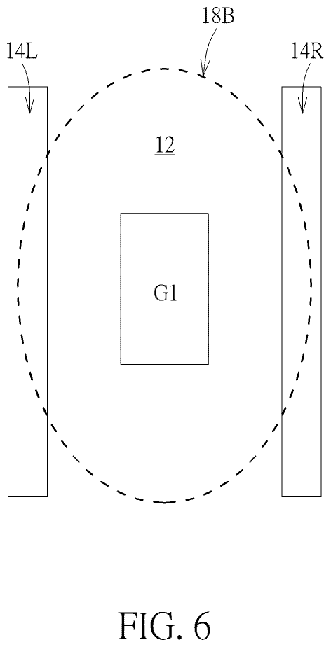

In the above embodiment, the first gate opening 18 in the peripheral region R1 has a rectangular shape, but in other embodiments of the present invention, the first gate opening 18 may be formed in other shapes. For example, FIG. 5 and FIG. 6 respectively show top views of the first gate structure, the first slot contact groove and the first gate opening in the peripheral region according to two other embodiments of the present invention. For the sake of simplicity, the second gate structure, the second slot contact groove and the second gate opening in the core region are not depicted in FIGS. 5 and 6, but their shapes can be shown with reference to FIG. 3, and they are not repeated here. As shown in FIG. 5, the shape of the first gate opening 18A is circular, and the first gate opening 18A also exposes the boundary of the first gate structure G1, part of the boundary of the first left slot contact groove 14L and part of the boundary of the first right slot contact groove 14R. Alternatively, as shown in FIG. 6, the shape of the first gate opening 18B is oval, and the first gate opening 18B also exposes the boundary of the first gate structure G1, part of the boundary of the first left slot contact groove 14L and part of the boundary of the first right slot contact groove 14R. The above variations are also within the scope of the present invention.

Based on the above description and drawings, the present invention provides a semiconductor structure including an alignment mark, which comprises a substrate 10 defining a peripheral region R1, a first gate structure G1 located in the peripheral region R1 on the substrate 10, wherein the first gate structure G1 has a left boundary G1L and a right boundary G1R, a dielectric layer 12 covering the first gate structure G1 of the peripheral region R1, a first left slot contact groove 14L located in the dielectric layer 12 on the left side of the first gate structure G1, a first right slot contact groove 14R located in the dielectric layer 12 on the right side of the first gate structure G1, and a first gate opening 18 exposes a left boundary G1L and a right boundary G1R of the first gate structure G1, a boundary of the first left slot contact groove 14L (that is, the right boundary 14LB) and a boundary of the first right slot contact groove 14R (that is, the left boundary 14RA).

In some embodiments of the present invention, the arrangement direction of the first left slot contact groove 14L, the arrangement direction of the first right slot contact groove 14R and the arrangement direction of the first gate structure G1 are parallel to each other (for example, in FIG. 3, all of them are arranged along the Y direction).

In some embodiments of the present invention, the first gate opening 18 overlaps with the first left slot contact groove 14L, the first right slot contact groove 14R and the first gate structure G1 when viewed from a top view.

In some embodiments of the present invention, the first gate opening 18 is rectangular, circular or elliptical when viewed from a top view.

In some embodiments of the present invention, the core region R2 is located next to the peripheral region R1, wherein the core region R2 includes at least a second gate structure G2, a second slot contact groove 16 and a second gate opening 20.

In some embodiments of the present invention, the arrangement direction of the second gate structure G2 and the arrangement direction of the second slot contact grooves 16 in the core region R2 are parallel to each other (for example, in FIG. 3, the second gate structure G2 and the second slot contact grooves 16 are both arranged along the Y direction).

In some embodiments of the present invention, when viewed from a top view, the second gate opening 20 in the core region R2 overlaps with a part of the second gate structure G2, but does not overlap with the second slot contact groove 16.

In some embodiments of the present invention, the area of the second gate opening 20 in the core region R2 is different from the area of the first gate opening 18 in the peripheral region R1 when viewed from a top view (as shown in FIG. 3, in the present invention, the area of the first gate opening 18 is generally larger than that of the second gate opening 20).

The invention also provides a method for measuring a semiconductor structure including an alignment mark, which comprises providing a substrate 10, defining a peripheral region R1 on the substrate 10, wherein the peripheral region R1 contains an alignment mark, and the alignment mark comprises a first gate structure G1 located in the peripheral region R1 on the substrate 10, wherein the first gate structure G1 has a left boundary G1L and a right boundary G1R, a dielectric layer 12 covers the first gate structure G1 in the peripheral region R1, a first left slot contact groove 14L is located in dielectric layer 12 and located on the left side of the first gate structure G1, a first right slot contact groove 14R is located in the dielectric layer 12 and located on the right side of the first gate structure G1, and a first gate opening 18 exposes a left boundary G1L and a right boundary G1R of the first gate structure G1, a boundary of the first left slot contact groove 14L (that is, a right boundary 14LB), and boundary of the first right slot contact groove 14R (that is, a left boundary 14RA).

In some embodiments of the present invention, the first gate opening 18 includes a left boundary 18L and a right boundary 18R, the first left slot contact groove 14L has a left boundary 14LA and a right boundary 14LB, wherein the right boundary 14LB is exposed by the first gate opening 18, and the first right slot contact groove 14R has a left boundary 14RA and a right boundary 14RB, wherein the left boundary 14RA is exposed by the first gate opening 18.

In some embodiments of the present invention, it further comprising measuring a distance from the left boundary 14LA of the first left slot contact groove 14L to the left boundary G1L of the first gate structure G1 is defined as a first distance X1, and measuring a distance from the right boundary 14RB of the first right slot contact groove 14R to the right boundary G1R of the first gate structure G1 is defined as a second distance X2, and subtracting the first distance X1 from the second distance X2 and dividing by 2 to obtain a first alignment value.

In some embodiments of the present invention, it further comprising measuring a distance from the left boundary 18L of the first gate opening 18 to the left boundary G1L of the first gate structure G1 is defined as a third distance X3, and measuring a distance from the right boundary 18R of the first gate opening 18 to the right boundary G1R of the first gate structure G1 is defined as a fourth distance X4, and subtracting the third distance X3 from the fourth distance X4 and dividing by 2 to obtain a second alignment value.

In some embodiments of the present invention, it further comprising measuring a distance from the left boundary 14LA of the first left slot contact groove 14L to the left boundary 18L of the first gate opening 18 is defined as a fifth distance X5, and measuring a distance from the right boundary 14RB of the first right slot contact groove 14R to the right boundary 18R of the first gate opening 18 is defined as a sixth distance X6, and subtracting the fifth distance X5 from the sixth distance X6 and dividing it by 2 to obtain a third alignment value.

In some embodiments of the present invention, the arrangement direction of the first left slot contact groove 14L, the arrangement direction of the first right slot contact groove 14R and the arrangement direction of the first gate structure G1 are parallel to each other.

In some embodiments of the present invention, the first gate opening 18 is rectangular, circular or elliptical when viewed from a top view.

In some embodiments of the present invention, the method further includes defining a core region R2 on the substrate 10, which is located next to the peripheral region R1, and forming at least a second gate structure G2, a second slot contact groove 16 and a second gate opening 20 in the core region R2.

In some embodiments of the present invention, the arrangement direction of the second gate structure G2 in the core region R2 and the arrangement direction of the second slot contact grooves 16 are parallel to each other (as shown in FIG. 3).

In some embodiments of the present invention, when viewed from a top view, the second gate opening 20 in the core region R2 overlaps with part of the second gate structure G2, but does not overlap with the second slot contact groove 16 (as shown in FIG. 3).

In some embodiments of the present invention, when viewed from a top view, the area of the second gate opening 20 in the core region R2 are different from the area of the first gate opening 18 in the peripheral region R1.

In some embodiments of the present invention, it further includes forming a metal layer 22 and filling the first left slot contact groove 14L, the first right slot contact groove 14R, the first gate opening 18 in the peripheral region R1, the second slot contact groove 16 and the second gate opening 20 in the core region R2.

To sum up, in the prior art, even if the first gate structure is formed in the peripheral region, the first gate structure is usually not regarded as a part of the alignment mark. The reason is that the first gate structure located in the peripheral region will be covered by the dielectric layer later, so from the top view, it is not easy to observe the position of the first gate structure, and the relative position of the first gate structure and other devices cannot be observed. The invention is characterized in that when the second gate opening is formed in the core region, the first gate opening is also formed in the peripheral region, wherein the first gate opening exposes the boundary of the first gate structure, the right boundary of the first left slot contact groove and the left boundary of the first right slot contact groove, so that the boundaries of the above elements become visible, and further comprising the left boundary of the first left slot contact groove and the right boundary of the first right slot contact groove which are originally visible from the top view direction. The boundaries of the above components can measure the distance from each other, and then calculate whether the relative position between the components is offset. Therefore, from the manufacturer's point of view, the position offset between the components can be found at the early stage of the process, and then the process parameters can be corrected to reduce the displacement and improve the quality of the components.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure with alignment marks, comprising:
a substrate defining a peripheral region;
a first gate structure located in the peripheral region on the substrate, wherein the first gate structure has a left boundary and a right boundary;
a dielectric layer covers the first gate structure in the peripheral region;
a first left slot contact groove located in the dielectric layer on a left side of the first gate structure;
a first right slot contact groove located in the dielectric layer on a right side of the first gate structure; and
a first gate opening exposing the left boundary of the first gate structure, the right boundary of the first gate structure, a boundary of the first left slot contact groove and a boundary of the first right slot contact groove.

2. The semiconductor structure including an alignment mark according to claim 1, wherein the arrangement direction of the first left slot contact groove and the arrangement direction of the first right slot contact groove are parallel to each other.

3. The semiconductor structure including an alignment mark according to claim 1, wherein the first gate opening overlaps the first left slot contact groove, the first right slot contact groove and the first gate structure when viewed from a top view.

4. The semiconductor structure including an alignment mark according to claim 1, wherein the first gate opening is rectangular, circular or elliptical when viewed from a top view.

5. The semiconductor structure including an alignment mark according to claim 1, further comprising a core region located next to the peripheral region, wherein the core region comprises at least a second gate structure, a second slot contact groove and a second gate opening.

6. The semiconductor structure including an alignment mark according to claim 5, wherein the arrangement direction of the second gate structure in the core region and the arrangement direction of the second slot contact grooves are parallel to each other.

7. The semiconductor structure including an alignment mark according to claim 5, wherein the second gate opening in the core region overlaps with part of the second gate structure, but does not overlap with the second slot contact groove when viewed from a top view.

8. The semiconductor structure including an alignment mark according to claim 5, wherein an area of the second gate opening in the core region is different from an area of the first gate opening in the peripheral region when viewed from a top view.

9. A method for measuring a semiconductor structure including an alignment mark, comprising:
providing a substrate, defining a peripheral region thereon;
forming an alignment mark in the peripheral region, and the alignment mark including:
a first gate structure located in the peripheral region on the substrate, wherein the first gate structure has a left boundary and a right boundary;
a dielectric layer covers the gate structure in the peripheral region;
a first left slot contact groove located in the dielectric layer on a left side of the first gate structure;
a first right slot contact groove located in the dielectric layer on a right side of the first gate structure; and
a first gate opening exposing the left boundary of the first gate structure, the right boundary of the first gate structure, a boundary of the first left slot contact groove and a boundary of the first right slot contact groove.

10. The method for measuring a semiconductor structure including an alignment mark according to claim 9, wherein:
the first gate opening includes a left boundary and a right boundary;
the first left slot contact groove has a left boundary and a right boundary, wherein the right boundary is exposed by the first gate opening;
the first right slot contact groove has a left boundary and a right boundary, wherein the left boundary is exposed by the first gate opening.

11. The method for measuring a semiconductor structure including an alignment mark according to claim 10, further comprising:
measuring a distance from the left boundary of the first left slot contact groove to the left boundary of the first gate structure, and defining the distance as a first distance;
measuring a distance from that right boundary of the first right slot contact groove to the right boundary of the first gate structure, and defining the distance as a second distance;
subtracting the first distance from the second distance and divide by 2 to obtain a first alignment value.

12. The method for measuring a semiconductor structure including an alignment mark according to claim 10, further comprising:
measuring a distance from the left boundary of the first gate opening to the left boundary of the first gate structure, and defining the distance as a third distance;
measuring a distance from the right boundary of the first gate opening to the right boundary of the first gate structure, and defining the distance as a fourth distance;
subtracting the third distance from the fourth distance and divide by 2 to obtain a second alignment value.

13. The method for measuring a semiconductor structure including an alignment mark according to claim 10, further comprising:
measuring a distance from that left boundary of the first left slot contact groove to the left boundary of the first gate opening, and defining the distance as a fifth distance;
measuring a distance from that right boundary of the first right slot contact groove to the right boundary of the first gate opening, and defining the distance as a sixth distance;
subtracting the fifth distance from the sixth distance and divide by 2 to obtain a third alignment value.

14. The method for measuring a semiconductor structure including an alignment mark according to claim 9, wherein the arrangement direction of the first left slot contact groove and the arrangement direction of the first right slot contact groove are parallel to each other.

15. The method for measuring a semiconductor structure including an alignment mark according to claim 9, wherein the first gate opening is rectangular, circular or elliptical when viewed from a top view.

16. The method for measuring a semiconductor structure including an alignment mark according to claim 9, wherein the method further comprises:
defining a core region on the substrate, which is located beside the peripheral region;
forming at least a second gate structure, a second slot contact groove and a second gate opening in the core region.

17. The method for measuring a semiconductor structure including an alignment mark according to claim 16, wherein the arrangement direction of the second gate structure in the core region and the arrangement direction of the second slot contact groove are parallel to each other.

18. The method for measuring a semiconductor structure including an alignment mark according to claim 16, wherein the second gate opening in the core region overlaps with part of the second gate structure, but does not overlap with the second slot contact groove when viewed from a top view.

19. The method for measuring a semiconductor structure including an alignment mark according to claim 16, wherein the area of the second gate opening in the core region is different from the area of the first gate opening in the peripheral region when viewed from a top view.

20. The method for measuring a semiconductor structure including an alignment mark according to claim 9, further comprising:
forming a metal layer, and the first left slot contact groove, the first right slot contact groove, the first gate opening, the second slot contact groove and the second gate opening in the core region are simultaneously filled by the metal layer.
